(19) United States
(12) Patent Application Publication
(10) Pub. No.: US 2025/0275396 A1
(43) Pub. Date: Aug. 28, 2025

(54) DISPLAY DEVICE

(71) Applicant: LG Display Co., Ltd., Seoul (KR)

(72) Inventors: Sikyu LEE, Paju-si (KR); Heejoong KIM, Paju-si (KR)

(73) Assignee: LG Display Co., Ltd., Seoul (KR)

(21) Appl. No.: 18/970,420

(22) Filed: Dec. 5, 2024

(30) Foreign Application Priority Data
Feb. 28, 2024 (KR) 10-2024-0028718

(51) Int. Cl. H10K 59/131; H10K 59/35

(52) U.S. Cl. CPC H10K 59/131; H10K 59/353

(57) ABSTRACT

A display device includes a first sub-pixel column including a plurality of first sub-pixels disposed in a first direction, a second sub-pixel column including a plurality of second sub-pixels disposed in the first direction and disposed at one side of the first sub-pixel column in a second direction intersecting the first direction, and a driving voltage line including a first driving voltage line disposed at the other side of the first sub-pixel in the second direction and extending along the first sub-pixel column and a second driving voltage line electrically connected to the first driving voltage line and electrically connected to a 1-1 sub-pixel among the plurality of first sub-pixels and a 2-1 sub-pixel among the plurality of second sub-pixels. The first sub-pixel column and the second sub-pixel column are disposed alternately. The second driving voltage line is between the first sub-pixel column and the second sub-pixel column.

### CROSS REFERENCE TO RELATED APPLICATION

The present application claims priority to Korean Patent Application No. 10-2024-0028718, filed Feb. 28, 2024, the entire contents of which is incorporated herein for all purposes by this reference.

### BACKGROUND

### Technical Field

The present specification relates to a display device.

### Discussion of the Related Art

As the information society develops, various demands for display devices for displaying images are increasing, and various types of display devices such as liquid crystal display (LCD) devices and organic light emitting diode (OLED) display devices are utilized.

A display panel of the display device may include a plurality of organic light emitting elements, and the organic light emitting element may include an anode, an organic layer, and a cathode.

### SUMMARY

Accordingly, embodiments of the present disclosure are directed to a display device that substantially obviates one or more of the problems due to limitations and disadvantages of the related art.

An aspect of the present disclosure is to provide a display device capable of increasing an aperture ratio by alternately arranging adjacent sub-pixel columns in a zigzag manner.

Another aspect of the present disclosure is to provide a display device capable of reducing light color mixing by alternately arranging adjacent sub-pixel columns in a zigzag manner.

Another aspect of the present disclosure is to provide a display device capable of reducing light color mixing between adjacent sub-pixel columns by alternately arranging the adjacent sub-pixel columns in a zigzag manner and locating a driving voltage line between the adjacent sub-pixel columns.

Another aspect of the present disclosure is to provide a display device capable of improving decoloring defect by easily extending a color filter.

Another aspect of the present disclosure is to provide a display device capable of easily adjusting an aperture ratio and a size of a transistor.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a display device comprises a first sub-pixel column including a plurality of first sub-pixels disposed in a first direction, a second sub-pixel column including a plurality of second sub-pixels disposed in the first direction and disposed at one side of the first sub-pixel column in a second direction intersecting the first direction, and a driving voltage line including a first driving voltage line disposed at the other side of the first sub-pixel in the second direction and extending along the first sub-pixel column and a second driving voltage line electrically connected to the first driving voltage line and electrically connected to a 1-1 sub-pixel among the plurality of first sub-pixels and a 2-1 sub-pixel among the plurality of second sub-pixels, in which the first sub-pixel column and the second sub-pixel column are disposed alternately, and the second driving voltage line is disposed between the first sub-pixel column and the second sub-pixel column.

Detailed matters of other embodiments are included in a detailed description and accompanying drawings.

According to the embodiments of the present specification, adjacent sub-pixel columns may be alternately disposed in a zigzag manner. The adjacent sub-pixel columns each include sub-pixels, and each sub-pixel of the adjacent sub-pixel columns may emit a different color. As a section in which the sub-pixels of adjacent sub-pixel columns overlap each other is longer, the possibility of the occurrence of light color mixing between the adjacent sub-pixel columns may is higher. However, according to the embodiments of the present specification, since the adjacent sub-pixel columns are disposed in the zigzag manner, it is possible to minimize the section in which the sub-pixels of each of the adjacent sub-pixel columns overlap each other, thereby improving light color mixing between adjacent sub-pixel columns.

According to the embodiments of the present specification, since the adjacent sub-pixel columns are disposed in the zigzag manner, it is possible to easily adjust the aperture ratio and size of the transistor, thereby increasing the aperture ratio.

According to the embodiments of the present specification, since the adjacent sub-pixel columns are disposed in the zigzag manner, it is possible to easily extend the color filter, thereby improving light color mixing between the adjacent sub-pixel columns.

According to the embodiments of the present specification, by locating the driving voltage line between the adjacent sub-pixel columns, it is possible to improve the light mixing between the adjacent sub-pixel columns.

According to the embodiments of the present specification, it is possible to improve the light color mixing between the adjacent sub-pixel columns, thereby achieving high efficiency and high color gamut.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain various principles.

FIG. 1 is a view schematically showing a display device according to a first embodiment.

FIG. 2 is a systematic exemplary view of the display device according to the first embodiment.

FIG. 3 is an exemplary view of a circuit constituting a sub-pixel in the display device according to the first embodiment.

FIG. 4 is a cross-sectional view of the sub-pixel according to the first embodiment.

FIG. 5 is a plan view showing a plurality of sub-pixel columns, a driving voltage line, and a reference voltage line according to the first embodiment.

FIG. 6 is a cross-sectional view along line A-A′ in FIG. 5.

FIG. 7 is a plan view showing a plurality of sub-pixel columns, a driving voltage line, and a reference voltage line according to a comparative example.

FIG. 8 is a schematic view showing that light color mixing of the display device according to the first embodiment has been prevented.

### DETAILED DESCRIPTION

Hereinafter, embodiments will be described with reference to the accompanying drawings. In the specification, when a first component (or an area, a layer, a portion, or the like) is described as “on,” “connected,” or “coupled to” a second component, it means that the first component may be directly connected/coupled to the second component or a third component may be disposed therebetween.

The same reference numerals indicate the same components. In addition, in the drawings, thicknesses, proportions, and dimensions of components are exaggerated for effective description of technical contents. The term “and/or” includes all one or more combinations that may be defined by the associated configurations.

Terms such as first and second may be used to describe various components, but the components are not limited by the terms. The terms are used only for the purpose of distinguishing one component from another. For example, a first component may be referred to as a second component, and similarly, the second component may also be referred to as the first component without departing from the scopes of the embodiments. The singular expression includes the plural expression unless the context clearly dictates otherwise.

Terms such as “under,” “at a lower side,” “above,” and “at an upper side” are used to describe the relationship between the components illustrated in the drawings. The terms are relative concepts and are described with respect to directions marked in the drawings.

It should be understood that term such as “includes” or “has” is intended to specify the presence of features, numbers, steps, operations, components, parts, or a combination thereof described in the specification and does not preclude the presence or addition possibility of one or more other features, numbers, steps, operations, components, parts, or combinations thereof in advance.

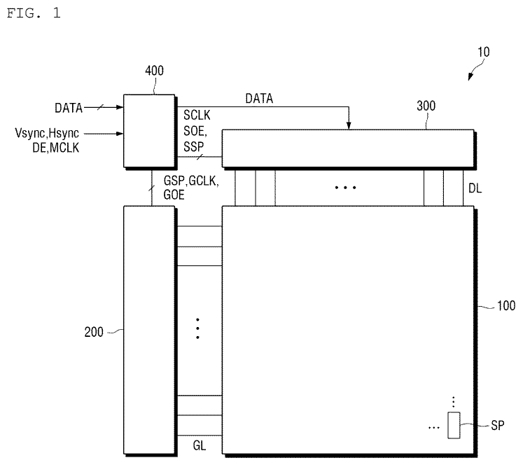

FIG. 1 is a view schematically showing a display device according to a first embodiment.

Referring to FIG. 1, a display device 10 according to the first embodiment may include a display panel 100 in which a plurality of gate lines GL and data lines DL are connected and a plurality of sub-pixels SP are disposed, a gate driving circuit 200 for providing signals to the plurality of gate lines GL, a data driving circuit 300 for supplying a data voltage through the plurality of data lines DL, and a timing controller 400 for controlling the gate driving circuit 200 and the data driving circuit 300.

The display panel 100 displays images based on a scan signal transmitted from the gate driving circuit 200 through the plurality of gate lines GL and a data voltage transmitted from the data driving circuit 300 through the plurality of data lines DL.

In the case of a liquid crystal display device, the display panel 100 may include a liquid crystal layer formed between two substrates and operate in any known mode of a twisted nematic (TN) mode, a vertical alignment (VA) mode, an in plane switching (IPS) mode, a fringe field switching (FFS) mode, and the like. On the other hand, in the case of an organic light emitting diode display device, the display panel 100 can be implemented in a top emission manner, a bottom emission manner, a dual emission manner, or the like.

The display panel 100 may include a plurality of pixels, each pixel may be formed of sub-pixels SP with different colors, for example, a white sub-pixel, a red sub-pixel, a green sub-pixel, and a blue sub-pixel, and each sub-pixel SP can be defined by the plurality of data lines DL and the plurality of gate lines GL.

One sub-pixel SP may include a thin film transistor TFT disposed in an area formed by one data line DL and one gate line GL, a light emitting element such as a light emitting diode that emits light according to a data voltage, a storage capacitor electrically connected to the light emitting element to maintain a voltage, and the like.

For example, when the display device 10 having the resolution of 2,600×3,840 is formed of four sub-pixels SP of white W, red R, green G, and blue B, 2,600 gate lines GL may be provided, and 15,360 data lines DL (3,840×4=15,360) may be provided by data lines DL (=3,840) each connected to each of four sub-pixels WRGB, and a sub-pixel SP may be disposed in each of areas formed by the gate lines GL and the data lines DL.

The gate driving circuit 200 is controlled by the timing controller 400 and controls driving timings of the plurality of sub-pixels SP by sequentially outputting scan signals to the plurality of gate lines GL disposed on the display panel 100.

In the display device 10 having the resolution of 2,600×3,840, a case in which scan signals are sequentially output from a first gate line to a 2,600th gate line with respect to the 2,600 gate lines GL can be referred to as “2,600-phase driving.” Alternatively, as in a case in which scan signals are sequentially output from the first gate line to the fourth gate line and then the scan signals are sequentially output from the fifth gate line to the eighth gate line, a case in which scan signals are sequentially output in units of four gate lines GL is referred to as “4-phase driving.” In other words, a case in which a scan signal is sequentially output to each of N gate lines GL can be referred to as “N-phase driving.”

In this case, the gate driving circuit 200 may include one or more gate driving integrated circuits GDIC and may be located at only one side of the display panel 100 or both sides depending on a driving method. Alternatively, the gate driving circuit 200 can be implemented in a form of a gate in panel (GIP) formed directly in a bezel area of the display panel 100.

The data driving circuit 300 receives digital image data DATA from the timing controller 400 and converts the received digital image data DATA into an analog data voltage. Then, by outputting a data voltage to each of the data lines DL according to the timing when the scan signal is applied through the gate line GL, each sub-pixel SP connected to the data line DL displays an emission signal at luminance corresponding to the data voltage.

Likewise, the data driving circuit 300 may include one or more source driving ICs SDIC, and the source driving IC SDIC may be connected to a bonding pad of the display panel 100 or disposed directly on the display panel 100 in a tape automated bonding (TAB) method or a chip on glass (COG) method.

In some cases, each source driving IC SDIC may be disposed integrally with the display panel 100. In addition, each source driving IC SDIC can be implemented in a chip on film (COF) method, and in this case, each source driving IC SDIC may be mounted on a circuit film and electrically connected to the data line DL of the display panel 100 through the circuit film.

The timing controller 400 supplies various control signals to the gate driving circuit 200 and the data driving circuit 300 and controls operations of the gate driving circuit 200 and the data driving circuit 300. In other words, the timing controller 400 controls the gate driving circuit 200 to output the scan signal according to the timing implemented in each frame and on the other hand, transmits digital image data DATA received from the outside to the data driving circuit 300.

In this case, the timing controller 400 receives various timing signals including a vertical synchronization signal Vsync, a horizontal synchronization signal Hsync, a data enable signal DE, a main clock MCLK, and the like in addition to the digital image data DATA from the outside (e.g., a host system). Therefore, the timing controller 400 generates the control signals using various timing signals received from the outside and transmits the control signals to the gate driving circuit 200 and the data driving circuit 300.

For example, the timing controller 400 outputs a gate start pulse GSP, a gate clock GCLK, a gate output enable signal GOE, and the like to control the gate driving circuit 200. Here, the gate start pulse GSP controls the timing at which one or more gate driving ICs GDIC constituting the gate driving circuit 200 start to operate. In addition, the gate clock GCLK is a clock signal commonly input to the one or more gate driving ICs GDIC and controls the shift timing of the scan signal. In addition, the gate output enable signal GOE specifies timing information of the one or more gate driving ICs GDIC.

In addition, the timing controller 400 outputs various data control signals including a source start pulse SSP, a source sampling clock SCLK, a source output enable signal SOE, and the like to control the data driving circuit 300. Here, the source start pulse SSP controls the timing at which one or more source driving integrated circuits SDIC constituting the data driving circuit 300 start sampling data. The source sampling clock SCLK is a clock signal that controls the timing of sampling data in the source driving integrated circuit SDIC. The source output enable signal SOE controls the output timing of the data driving circuit 300.

The display device 10 may further include a power management integrated circuit for supplying various voltages or currents to the display panel 100, the gate driving circuit 200, the data driving circuit 300, and the like or controlling the various voltages or currents to be supplied.

Meanwhile, a light emitting element may be disposed in each sub-pixel SP. For example, an organic light emitting display device may include a light emitting element, such as a light emitting diode, in each sub-pixel SP and may display images by controlling a current flowing through the light emitting element according to a data voltage.

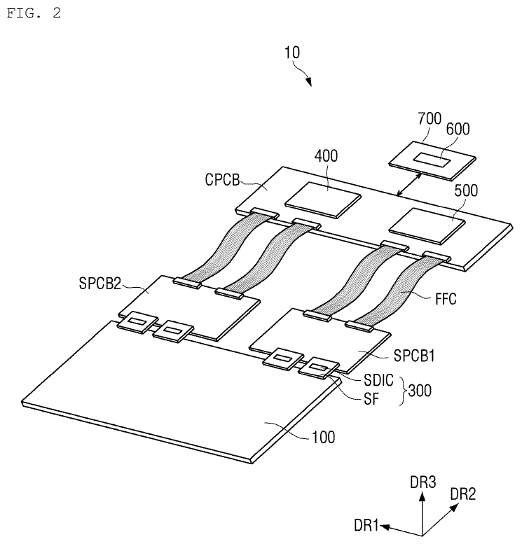

FIG. 2 is a systematic exemplary view of the display device according to the first embodiment.

Referring to FIG. 2, the display device 10 according to the first embodiment shows a case where the source driving integrated circuit SDIC included in the data driving circuit 300 is implemented in a form of a chip on film (COF) among various types (TAB, COG, COF, and the like), and the gate driving circuit 200 is implemented in a form of the GIP among various types (TAB, COG, COF, GIP, and the like).

When the gate driving circuit 200 is implemented in the form of the GIP, a plurality of gate driving integrated circuits GDIC included in the gate driving circuit 200 may be formed directly in the bezel area of the display panel 100. In this case, the gate driving integrated circuit GDIC may receive various signals (a clock signal, a gate high signal, a gate low signal, and the like) required for generating the scan signal SCAN through gate driving-related signal wirings disposed in the bezel area.

Likewise, one or more source driving integrated circuits SDIC included in the data driving circuit 300 may each be mounted on a source film SF, and one side of the source film SF may be electrically connected to the display panel 100. In addition, wires for electrically connecting the source driving integrated circuit SDIC with the display panel 100 may be disposed on the source film SF.

The display device 10 may include at least one source printed circuit board SPCB for circuitry connection between the plurality of source driving integrated circuits SDIC and other devices and a control printed circuit board CPCB on which control components and various electrical components are mounted.

In this case, the other side of the source film SF on which the source driving integrated circuit SDIC is mounted may be connected to the at least one source printed circuit board SPCB. In other words, the source film SF on which the source driving integrated circuit SDIC is mounted may have one side electrically connected to the display panel 100 and the other side electrically connected to the source printed circuit board SPCB. For example, a plurality of source films SF may be connected to one source printed circuit board SPCB, but is not limited thereto.

The timing controller 400 and a power management IC (PMIC) 500 may be mounted on the control printed circuit board CPCB. The timing controller 400 may control operations of the data driving circuit 300 and the gate driving circuit 200. The PMIC 500 may supply a driving voltage or current to the display panel 100, the data driving circuit 300, the gate driving circuit 200, and the like and control the supplied voltage or current.

The at least one source printed circuit board SPCB and the control printed circuit board CPCB may be connected circuitously through at least one connecting member, and the connecting member may include, for example, a flexible printed circuit (FPC), a flexible flat cable (FFC), and the like. For example, a plurality of source printed circuit boards SPCB may be present, and the plurality of source printed circuit boards SPCB may be connected to one control printed circuit board CPCB. In this case, one source printed circuit board SPCB may be connected to the control printed circuit board CPCB through a plurality of flexible flat cables FFC. FIG. 2 exemplarily shows two source printed circuit boards SPCB, four flexible flat cables FFC, and one control printed circuit board CPCB, but the present specification is not limited thereto.

The display device 10 may further include a set board 700 electrically connected to the control printed circuit board CPCB. In this case, the set board 700 may also be referred to as a power board. The set board 700 may include a main power management circuit (M-PMC) 600 for managing the overall power of the display device 10. The M-PMC 600 may be interworked with the PMIC 500.

In the case of the display device 10 having the above configuration, the driving voltage is generated from the set board 700 and transmitted to the PMIC 500 in the control printed circuit board CPCB. The PMIC 500 transmits a driving voltage required for display driving or characteristic value sensing to the source printed circuit board SPCB through the flexible printed circuit FPC or the flexible flat cable FFC. The driving voltage transmitted to the source printed circuit board SPCB is supplied to emit or sense a specific sub-pixel SP in the display panel 100 through the source driving integrated circuit SDIC.

In this case, each sub-pixel SP arranged on the display panel 100 in the display device 10 may include a light emitting element and a circuit element such as a driving transistor for driving the light emitting element.

The type and number of circuit elements forming each sub-pixel SP may be determined in any of various ways according to the provided function and design method.

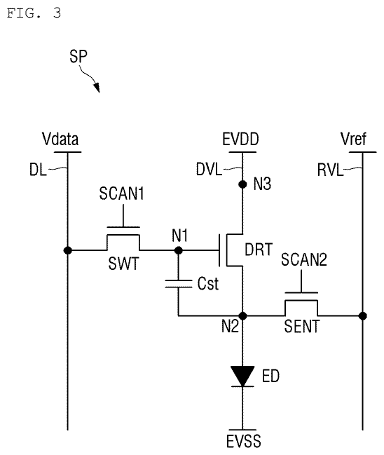

FIG. 3 is an exemplary view of a circuit constituting a sub-pixel in the display device according to the first embodiment.

Referring to FIG. 3, in the display device 10 according to the first embodiment, the sub-pixel SP may include one or more transistors and a capacitor, and an organic light emitting diode may be disposed as the light emitting element ED.

For example, the sub-pixel SP may include a driving transistor DRT, a switching transistor SWT, a sensing transistor SENT, a storage capacitor Cst, and the light emitting element ED.

The driving transistor DRT has a first node N1, a second node N2, and a third node N3. The first node N1 of the driving transistor DRT may be a gate node to which a data voltage Vdata from the data driving circuit 300 through the data line DL when the switching transistor SWT is turned on. The second node N2 of the driving transistor DRT may be electrically connected to an anode of the light emitting element ED and may be a source node or a drain node. The third node N3 of the driving transistor DRT may be electrically connected to a driving voltage line DVL to which a driving voltage EVDD is applied and may be a drain node or a source node.

In this case, during a display driving period, the driving voltage EVDD required to display images may be supplied through the driving voltage line DVL, and for example, the driving voltage EVDD required to display the images may be 27 V.

The switching transistor SWT is electrically connected between the first node N1 of the driving transistor DRT and the data line DL, and the gate line GL is connected to the gate node to operate according to the scan signal SCAN supplied through the gate line GL. In addition, when the switching transistor SWT is turned on, the operation of the driving transistor DRT is controlled by transmitting the data voltage Vdata supplied through the data line DL to the gate node of the driving transistor DRT.

The sensing transistor SENT is electrically connected between the second node N2 of the driving transistor DRT and a reference voltage line RVL, and the gate line GL is connected to the gate node to operate according to a sense signal SENSE supplied through the gate line GL. When the sensing transistor SENT is turned on, a sensing reference voltage Vref supplied through the reference voltage line RVL is transmitted to the second node N2 of the driving transistor DRT.

In other words, a voltage at the first node N1 and a voltage at the second node N2 of the driving transistor DRT are controlled by controlling the switching transistor SWT and the sensing transistor SENT, and thus a current for driving the light emitting element ED may be supplied.

Gate nodes of the switching transistor SWT and the sensing transistor SENT may be connected together to the one gate line GL or may be connected to different gate lines GL. Here, a structure in which the switching transistor SWT and the sensing transistor SENT are connected to different gate lines GL is shown as an example, and in this case, the switching transistor SWT and the sensing transistor SENT may be independently controlled by the scan signal SCAN and the sense signal SENSE that are transmitted through different gate lines GL.

On the other hand, when the switching transistor SWT and the sensing transistor SENT are connected to one gate line GL, the switching transistor SWT and the sensing transistor SENT may be simultaneously controlled by the scan signal SCAN or the sense signal SENSE transmitted through the one gate line GL, and an aperture ratio of the sub-pixel SP may be increased.

Meanwhile, the transistors disposed in the sub-pixel SP may be formed of both an n-type transistor and a p-type transistor, and here, the case of being formed of the n-type transistor is shown as an example.

The storage capacitor Cst is electrically connected between the first node N1 and the second node N2 of the driving transistor DRT and maintains the data voltage Vdata for one frame.

The storage capacitor Cst may be connected between the first node N1 and the third node N3 of the driving transistor DRT depending on the type of the driving transistor DRT. The anode of the light emitting element ED may be electrically connected to the second node N2 of the driving transistor DRT, and a base voltage EVSS may be applied to the cathode of the light emitting element ED.

Here, the base voltage EVSS may be a ground voltage or a voltage higher or lower than the ground voltage. In addition, the base voltage EVSS may be changed depending on a driving state, and for example, the base voltage EVSS at the time of display driving and the base voltage EVSS at the time of sensing driving may be set differently.

The above-described structure of the sub-pixel SP is a 3T (transistor) 1C (capacitor) structure, which is only an example for description, and the sub-pixel SP may further include one or more transistors or in some cases, one or more capacitors. Alternatively, each of the plurality of sub-pixels SP may have the same structure, or some of the plurality of sub-pixels SP may have different structures.

The display device 10 according to the first embodiment may use a method of measuring a current flowing by a voltage charged in the storage capacitor Cst in a characteristic value sensing section of the driving transistor DRT to effectively sense the characteristic value of the driving transistor DRT, such as a threshold voltage or mobility, which is referred to as current sensing.

In other words, by measuring the current flowing by the voltage charged in the storage capacitor Cst in the characteristic value sensing section of the driving transistor DRT, the characteristic value or a change in characteristic value of the driving transistor DRT in the sub-pixel SP may be identified.

In this case, since the reference voltage line RVL not only serves to transmit the reference voltage Vref but also serves as a sensing line for sensing the characteristic value of the driving transistor DRT in the sub-pixel SP, the reference voltage line RVL may be referred to as a sensing line.

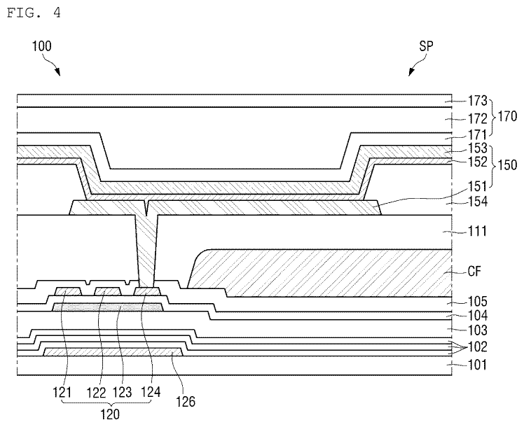

FIG. 4 is a cross-sectional view of the sub-pixel according to the first embodiment. FIG. 4 shows a cross-sectional view of the sub-pixel SP of the display panel 100.

Referring to FIGS. 1 to 4, the display panel 100 may include a substrate 101, a first thin film transistor 120, a light emitting part 150, and an encapsulation part 170.

The substrate 101 may be a rigid substrate such as glass or quartz, or a flexible substrate containing a plastic material. For example, the substrate 101 may be a multi-substrate including a plurality of plastic materials such as polyimide, but the embodiments of the present specification are not limited thereto.

A light blocking layer 126 may be disposed on the substrate 101. Hereinafter, a conductive layer on which the light blocking layer 126 is disposed is referred to as a first conductive layer. The light blocking layer 126 can prevent light from transmitting a first semiconductor layer 123 of the first thin film transistor 120. For example, the first semiconductor layer 123 may be disposed to overlap the light blocking layer 126. The light blocking layer 126 may be formed of a single layer or multiple layers made of any one of molybdenum (Mo), aluminum (Al), chromium (Cr), nickel (Ni), neodymium (Nd), and copper (Cu) or an alloy thereof, but the embodiments of the present specification are not limited thereto.

A buffer layer 102 may be disposed on the light blocking layer 126. The buffer layer 102 can minimize or reduce the diffusion of moisture or oxygen permeating the substrate 101. The buffer layer 102 may be formed by alternately stacking silicon nitride (SiNₓ) and silicon oxide (SiOₓ) at least once, but the embodiments of the present specification are not limited thereto.

A first insulating layer 103 may be disposed on the buffer layer 102. The first insulating layer 103 can prevent a short between a component of the first thin film transistor 120 and the light blocking layer 126. The first insulating layer 103 may be made of the same material as the buffer layer 102, but the embodiments of the present specification are not limited thereto. For example, the first insulating layer 103 may be made of an inorganic material, such as silicon nitride (SiNₓ) or silicon oxide (SiOₓ), but the embodiments of the present specification are not limited thereto.

The first thin film transistor 120 may be disposed on the first insulating layer 103. The first thin film transistor 120 may include a first source electrode 121, a first gate electrode 122, the first semiconductor layer 123, and a first drain electrode 124.

The first semiconductor layer 123 may be disposed on the first insulating layer 103. The first semiconductor layer 123 may include a metal oxide semiconductor, such as indium-gallium-zinc oxide (IGZO), and a material, such as amorphous silicon, low temperature polycrystalline silicon, or polycrystalline silicon, but the embodiments of the present specification are not limited thereto. The first semiconductor layer 123 may include a channel area, a source area, and a drain area.

Since the low temperature polycrystalline silicon semiconductor layer or the polycrystalline silicon semiconductor layer has higher mobility than the amorphous semiconductor layer and the oxide semiconductor layer, consumption power can be low and reliability can be excellent. Therefore, the driving transistor may be formed of the low temperature polycrystalline silicon semiconductor layer or the polycrystalline silicon semiconductor layer, but the embodiments of the present specification are not limited thereto.

A second insulating layer 104 may be disposed on the first semiconductor layer 123. The second insulating layer 104 may be made of the same material as the first insulating layer 103, but the embodiments of the present specification are not limited thereto. The second insulating layer 104 can prevent a short between the first semiconductor layer 123 and another component of the first thin film transistor 120. The second insulating layer 104 may be a gate insulating layer, but is not limited thereto.

A first gate electrode 122 may be disposed on the second insulating layer 104. The first gate electrode 122 may be disposed on the second insulating layer 104 to overlap the channel area of the first semiconductor layer 123. The first gate electrode 122 may be formed of a single layer or multiple layers made of molybdenum (Mo), copper (Cu), titanium (Ti), aluminum (Al), chromium (Cr), gold (Au), nickel (Ni), neodymium (Nd), or compounds thereof, but the embodiments of the present specification are not limited thereto. The first gate electrode 122 may be disposed together with the gate line, but the embodiments of the present specification are not limited thereto. Hereinafter, a conductive layer on which the first gate electrode 122 is disposed is referred to as a second conductive layer. The first source electrode 121 and the first drain electrode 124 may be disposed on the second conductive layer. The first source electrode 121 and the first drain electrode 124 may be electrically connected to the first semiconductor layer 123 through contact holes.

A third insulating layer 105 may be disposed on the second conductive layer. The third insulating layer 105 may be made of the same material as the first insulating layer 103 or the second insulating layer 104, but the embodiments of the present specification are not limited thereto. The third insulating layer 105 may be a passivation layer, but is not limited thereto.

A color filter CF may be disposed on the third insulating layer. The color filter CF may be provided in each of first to fourth sub-pixels. For example, the color filter CF may include a first color filter disposed in the first sub-pixel, a second color filter disposed in the second sub-pixel, and a third color filter disposed in the fourth sub-pixel. The first color filter provided in the first sub-pixel may be provided to block light of other colors excluding red (R) light. In this case, the first color filter may be provided as a red color filter. The second color filter provided in the second sub-pixel may be provided to block light of other colors excluding green (G) light. In this case, the second color filter 93 may be provided as a green color filter. The third color filter provided in the fourth sub-pixel may be provided to block light of other colors excluding blue (B) light. In this case, the third color filter may be provided as a blue color filter. However, the embodiments of the present specification are not necessarily limited thereto.

A first protective layer 111 may be disposed on the color filter CF. The first protective layer 111 may be made of an organic material. For example, the first protective layer 111 may be made of an organic material containing an acrylic resin, an epoxy resin, a phenolic resin, a polyamide resin, or a polyimide resin, but the embodiments of the present specification are not limited thereto.

The light emitting part 150 may be disposed on the first protective layer 111. The light emitting part 150 may include an anode 151, an organic layer 152, and a cathode 153.

The anode 151 may be disposed on the first protective layer 111. The anode 151 may be electrically connected to the first thin film transistor 120 through a contact hole formed in the first protective layer 111. The anode 151 may be a reflective electrode that reflects light, but the embodiments of the present specification are not limited thereto. The anode 151 may include a metal material with high reflectivity, such as a stacking structure (Ti/Al/Ti) of aluminum (Al) and titanium (Ti), a stacking structure (ITO/Al/ITO) of aluminum (Al) and indium tin oxide (ITO), or an APC alloy, and may be formed of a single layer or multiple layers, but the embodiments of the present specification are not limited thereto. Hereinafter, a conductive layer on which the anode 151 is disposed is referred to as a third conductive layer.

The organic layer 152 may be disposed on the anode 151. The organic layer 152 may include one or more light emitting structures (or light emitting elements or elements) stacked on the anode 151 in the order or reverse order of a hole transport layer and an electron transport layer. For example, the hole transfer layer may include a hole transport layer, a hole injection layer, an electron blocking layer, a p-type charge generation layer, or the like, but the embodiments of the present specification are not limited thereto. For example, the electron transfer layer may include an electron transport layer, an electron injection layer, a hole blocking layer, an n-type charge generation layer, or the like, but the embodiments of the present specification are not limited thereto. The organic layer 152 may be an organic light emitting layer, an inorganic light emitting layer, a quantum dot light emitting layer, a micro light emitting diode, a micro mini light emitting diode, or the like, but the embodiments of the present specification area not limited thereto. For example, the organic layer 152 of the display panel 100 according to one embodiment of the present specification may include the organic light emitting layer. The organic layer 152 may include a red light emitting layer, a green light emitting layer, and a blue light emitting layer. The organic layer 152 may be a white light emitting layer, but the embodiments of the present specification are not limited thereto.

The cathode 153 may be disposed on the organic layer 152. The cathode 153 may be a transparent electrode that reflects light, but the embodiments of the present specification are not limited thereto. For example, the cathode 153 may include a transparent conductive material, such as indium tin oxide (ITO) or indium zinc oxide (IZO), or a metal that transmits visible light.

The bank 154 may be disposed to expose the anode 151. The bank 154 may define an opening (or an emission area) of the pixel and may be disposed to cover an edge portion of the anode 151.

The bank 154 may be made of a material containing black pigment, or an organic material such as a benzocyclobutene resin, a polyimide resin, an acrylic resin, or a photosensitive polymer, but the embodiments of the present specification are not limited thereto. When the bank 154 is made of a material containing black pigment or black dye, it may be a black bank. When the bank is made of a material containing black pigment or black dye, it is possible to block light from the outside or light reflected from the outside, thereby further increasing the luminance of the display device.

The encapsulation part 170 may be disposed on the bank 154 or the light emitting part 150. The encapsulation part 170 may include one or more insulating layers. For example, the encapsulation part 170 may include a first encapsulation layer 171, a second encapsulation layer 172 disposed on the first encapsulation layer 171, and a third encapsulation layer 173 disposed on the second encapsulation layer 172. The encapsulation part 170 may include one or more inorganic layers and one or more organic layers. For example, the first encapsulation layer 171 and the third encapsulation layer 173 may include an inorganic material, and the second encapsulation layer 172 may include an organic material, but the embodiments of the present specification are not limited thereto.

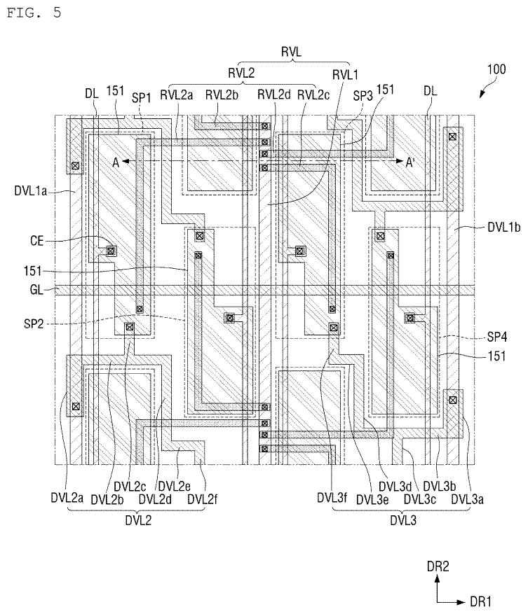

FIG. 5 is a plan view showing a plurality of sub-pixel columns, a driving voltage line, and a reference voltage line according to the first embodiment.

Referring to FIGS. 1 to 5, the pixels of the display device 10 according to the first embodiment may include a first sub-pixel SP1, a second sub-pixel SP2, a third sub-pixel SP3, and a fourth sub-pixel SP4. The first sub-pixel SP1 may be a red sub-pixel, the second sub-pixel SP2 may be a green sub-pixel, the third sub-pixel SP3 may be a white sub-pixel, and the fourth sub-pixel SP4 may be a blue sub-pixel. A plurality of first sub-pixels SP1 may be present, and the plurality of first sub-pixels SP1 may be arranged in a second direction DR2. A plurality of second sub-pixels SP2 may be present, and the plurality of second sub-pixels SP2 may be arranged in the second direction DR2. A plurality of third sub-pixels SP3 may be present, and the plurality of third sub-pixels SP3 may be arranged in the second direction DR2. A plurality of fourth sub-pixels SP4 may be present, and the plurality of fourth sub-pixels SP4 may be arranged in the second direction DR2. The plurality of first sub-pixels SP1 may constitute a first sub-pixel column, the plurality of second sub-pixels SP2 may constitute a second sub-pixel column, the third sub-pixels SP3 may constitute a third sub-pixel column, and the fourth sub-pixels SP4 may constitute a fourth sub-pixel column.

The second sub-pixel column may be disposed adjacent to one side of the first sub-pixel column in a first direction DR1, the third sub-pixel column may be disposed adjacent to one side of the second sub-pixel column in the first direction DR1, and the fourth sub-pixel column may be disposed adjacent to one side of the third sub-pixel column in the first direction DR1. The anode 151 may be disposed in each of the first sub-pixel SP1, the second sub-pixel SP2, the third sub-pixel SP3, and the fourth sub-pixel SP4.

The first to fourth sub-pixel columns may each be disposed in a zigzag manner with adjacent sub-pixel columns. For example, the first sub-pixel column and the second sub-pixel column may be disposed alternately, the second sub-pixel column and the third sub-pixel column may be disposed alternately, and the third sub-pixel column and the fourth sub-pixel column may be disposed alternately. In the present specification, the alternate arrangement may mean that the plurality of first sub-pixels SP1 constituting the first sub-pixel column and the plurality of second sub-pixels SP2 constituting the second sub-pixel column do not fully overlap but partially overlap each other. As shown in FIG. 5, for example, only a portion the first sub-pixel SP1 may overlap the second sub-pixels SP2 of the second sub-pixel column in the first direction DR1. For example, the first sub-pixel SP1 may overlap an upper end portion of any one second sub-pixel SP2 of the second sub-pixel column in the first direction DR1 and overlap a lower end portion of another second sub-pixel SP2 in the first direction DR1.

Hereinafter, for convenience of description of the sub-pixels SP1, SP2, SP3, and SP4 of each sub-pixel column, as shown in FIG. 5, the first sub-pixel SP1 disposed on an upper portion of the first sub-pixel column is referred to as a 1-1 sub-pixel and the first sub-pixel SP1 disposed on a lower portion thereof is referred to as a 1-2 sub-pixel, the second sub-pixel SP2 disposed on an upper portion of the second sub-pixel column is referred to as a 2-1 sub-pixel and the second sub-pixel SP2 disposed on a lower portion thereof is referred to as a 2-2 sub-pixel, the third sub-pixel SP3 disposed on an upper portion of the third sub-pixel column is referred to as a 3-1 sub-pixel and the third sub-pixel SP3 disposed on a lower portion thereof is referred to as a 3-2 sub-pixel, and the fourth sub-pixel SP4 disposed on an upper portion of the fourth sub-pixel column is referred to as a 4-1 sub-pixel and the fourth sub-pixel SP4 disposed on a lower portion thereof is referred to as a 4-2 sub-pixel.

The first to fourth sub-pixel columns are disposed alternately with adjacent sub-pixel columns in the zigzag manner, and the sub-pixels SP1, SP2, SP3, and SP4 of the sub-pixel columns emit light with different colors. When the first to fourth sub-pixel columns are disposed to fully overlap the adjacent sub-pixel columns in the first direction DR1, there may be a high possibility of light color mixing. However, in the case of the display device 10 according to the first embodiment, the first to fourth sub-pixel columns are disposed in the zigzag manner with the adjacent sub-pixel columns, respectively, so that the first to fourth sub-pixel columns are disposed to partially overlap the adjacent sub-pixel columns, respectively, in the first direction DR1, thereby minimizing light color mixing.

In addition, in the case of the display device 10 according to the first embodiment, the first to fourth sub-pixel columns may be disposed in the zigzag manner with the adjacent sub-pixel columns, respectively, to easily adjust the aperture ratio and the size of the transistor, thereby increasing the aperture ratio.

In addition, in the case of the display device 10 according to the first embodiment, the first to fourth sub-pixel columns may be disposed in the zigzag manner with the adjacent sub-pixel columns to easily extend the color filter, thereby minimizing the light color mixing between the adjacent sub-pixel columns.

The display panel 100 may include the data lines DL, the reference voltage line RVL, and the driving voltage line DVL that extend in the second direction DR2, and the gate line GL extending in the first direction DR1.

The first to fourth sub-pixel columns may each be electrically connected to the data line DL. The data line DL may be located on the first conductive layer, but is not limited thereto. The data line DL may be electrically connected to the sub-pixels SP1, SP2, SP3, and SP4 through connection electrodes CE. The connection electrode CE may be located on the second conductive layer, but is not limited thereto.

The first to fourth sub-pixel columns may each be electrically connected to the gate line GL. The gate line GL may be located on the second conductive layer, but is not limited thereto.

The first to fourth sub-pixel columns may each be electrically connected to the reference voltage line RVL. The reference voltage line RVL may be disposed between the second sub-pixel column and the third sub-pixel column. The reference voltage line RVL may include a first reference voltage line RVL1 and a second reference voltage line RVL2 electrically connected to the first reference voltage line RVL1. The first reference voltage line RVL1 may be located on the first conductive layer, but is not limited thereto. The second reference voltage line RVL2 may electrically connect the first reference voltage line RVL1 with each sub-pixel column. The second reference voltage line RVL2 may be located coplanarly with the first semiconductor layer 123 of FIG. 4. The second reference voltage line RVL2 may be electrically connected to each of the first to fourth sub-pixel columns. To this end, the second reference voltage line RVL2 may include a 2-1 reference voltage line RVL2a electrically connected to the first sub-pixel column, a 2-2 reference voltage line RVL2b electrically connected to the second sub-pixel column, a 2-3 reference voltage line RVL2c electrically connected to the third sub-pixel column, and a 2-4 reference voltage line RVL2d electrically connected to the fourth sub-pixel column.

One 2-1 reference voltage line RVL2a may be electrically connected to an upper end of the first reference voltage line RVL1 and electrically connected to the 1-1 sub-pixel. The 2-1 reference voltage line RVL2a may extend to the other side in the first direction DR1 and extend by being bent to the other side in the second direction DR2 so as to be electrically connected to the 1-1 sub-pixel.

The other 2-1 reference voltage line RVL2a may be electrically connected to a lower end of the first reference voltage line RVL1 and electrically connected to the 1-2 sub-pixel. The 2-1 reference voltage line RVL2a may extend to the other side in the first direction DR1 and extend by being bent to the other side to extend in the second direction DR2 so as to be electrically connected to the 1-2 sub-pixel.

One 2-2 reference voltage line RVL2b may be electrically connected to the upper end of the first reference voltage line RVL1 and electrically connected to the 2-1 sub-pixel. The 2-2 reference voltage line RVL2b may extend to the other side in the first direction DR1 and be bent to one side to extend in the second direction DR2 so as to be electrically connected to the 2-1 sub-pixel.

The other 2-2 reference voltage line RVL2b may be electrically connected to the lower end of the first reference voltage line RVL1 and electrically connected to the 2-2 sub-pixel. The 2-2 reference voltage line RVL2b may extend to the other side in the first direction DR1 and extend by being bent to one side in the second direction DR2 so as to be electrically connected to the 2-2 sub-pixel.

One 2-3 reference voltage line RVL2c may be electrically connected to the upper end of the first reference voltage line RVL1 and electrically connected to the 3-1 sub-pixel. The 2-3 reference voltage line RVL2c may extend to one side in the first direction DR1 and extend by being bent to the other side in the second direction DR2 so as to be electrically connected to the 3-1 sub-pixel.

The other 2-3 reference voltage line RVL2c may be electrically connected to the lower end of the first reference voltage line RVL1 and electrically connected to the 3-2 sub-pixel. The 3-2 reference voltage line RVL2c may extend to one side in the first direction DR1 and extend by being bent to the other side in the second direction DR2 so as to be electrically connected to the 2-3 sub-pixel.

One 2-4 reference voltage line RVL2d may be electrically connected to the upper end of the first reference voltage line RVL1 and electrically connected to the 4-1 sub-pixel. The 2-4 reference voltage line RVL2d may extend to one side in the first direction DR1 and extend by being bent to one side in the second direction DR2 so as to be electrically connected to the 4-1 sub-pixel.

The other 2-4 reference voltage line RVL2d may be electrically connected to the lower end of the first reference voltage line RVL1 and electrically connected to the 4-2 sub-pixel. The 4-2 reference voltage line RVL2d may extend to one side in the first direction DR1 and extend by being bent to one side in the second direction DR2 so as to be electrically connected to the 4-2 sub-pixel.

The driving voltage line DVL may include first driving voltage lines DVLla and DVL1b, a second driving voltage line DVL2, and a third driving voltage line DVL3.

The first driving voltage lines DVL1a and DVL1b may include the 1-1 driving voltage line DVLla located at the other side of the first sub-pixel column in the first direction DR1, and the 1-2 driving voltage line DVL1b located at one side of the fourth sub-pixel column in the first direction DR1. The first to fourth sub-pixel columns may be arranged in the first direction DR1 and repeatedly disposed in the first direction DR1. Therefore, the 1-2 driving voltage line DVL1b may be the same line as the 1-1 driving voltage line DVLla. However, for convenience of description, the 1-1 driving voltage line DVLla and the 1-2 driving voltage line DVL1b will be described separately. The second driving voltage line DVL2 and the third driving voltage line DVL3 may be electrically connected to the first driving voltage lines DVLla and DVL1b, respectively. Since the 1-1 driving voltage line DVLla and the 1-2 driving voltage line DVL1b may be the same line, the second driving voltage line DVL2 and the third driving voltage line DVL3 that are electrically connected to the first driving voltage lines DVLla and DVL1b, respectively may also be substantially the same line. However, for convenience of description, the second driving voltage line DVL2 and the third driving voltage line DVL3 will be described separately.

The second driving voltage line DVL2 may be electrically connected to the 1-1 driving voltage line DVLla. A plurality of second driving voltage lines DVL2 may be provided. The plurality of second driving voltage lines DVL2 may be repeatedly disposed in the second direction DR2.

Any one of the plurality of second driving voltage lines DVL2 may include a 2-1 driving voltage line DVL2a extending in the second direction DR2 and electrically connected to the 1-1 driving voltage line DVL1a, a 2-2 driving voltage line DVL2b connected to the 2-1 driving voltage line DVL2a and extending in the first direction DR1, a 2-3 driving voltage line DVL2c branched from the 2-2 driving voltage line DVL2b and extending to one side in the second direction DR2, a 2-4 driving voltage line DVL2d extending by being bent to the other side in the second direction DR2 from the 2-2 driving voltage line DVL2b, a 2-5 driving voltage line DVL2e extending by being bent to one side in the first direction DR1 from the 2-4 driving voltage line DVL2d, and a 2-6 driving voltage line DVL2f extending by being bent to the other side in the second direction DR2 from the 2-5 driving voltage line DVL2e. The 2-2 driving voltage line DVL2b may be disposed between the 1-1 sub-pixel and the 1-2 sub-pixel and electrically connected to the 1-1 sub-pixel. The 2-6 driving voltage line DVL2f may be electrically connected to the 2-3 sub-pixel disposed adjacent to the other side of the 2-2 sub-pixel in the second direction DR2. The second driving voltage line DVL2 may be repeatedly disposed in the second direction DR2. The 2-4 driving voltage line DVL2d may be disposed between the 1-1 sub-pixel and the 2-1 sub-pixel.

The 2-1 driving voltage line DVL2a of another second driving voltage line DVL2 among the plurality of second driving voltage lines DVL2 may be connected to an upper end of the 1-1 driving voltage line DVLla, and the 2-6 driving voltage line DVL2f of another second driving voltage line DVL2 may be electrically connected to the 2-2 sub-pixel.

The second driving voltage line DVL2 may be electrically connected to the 1-1 driving voltage line DVLla. The plurality of second driving voltage lines DVL2 may be provided.

Any one of the plurality of second driving voltage lines DVL2 may include a 2-1 driving voltage line DVL2a extending in the second direction DR2 and electrically connected to the 1-1 driving voltage line DVLla, a 2-2 driving voltage line DVL2b connected to the 2-1 driving voltage line DVL2a and extending in the first direction DR1, a 2-3 driving voltage line DVL2c branched from the 2-2 driving voltage line DVL2b and extending to one side in the second direction DR2, a 2-4 driving voltage line DVL2d extending by being bent to the other side in the second direction DR2 from the 2-2 driving voltage line DVL2b, a 2-5 driving voltage line DVL2e extending by being bent to one side in the first direction DR1 from the 2-4 driving voltage line DVL2d, and a 2-6 driving voltage line DVL2f extending by being bent to the other side in the second direction DR2 from the 2-5 driving voltage line DVL2e. The 2-2 driving voltage line DVL2b may be disposed between the 1-1 sub-pixel and the 1-2 sub-pixel and electrically connected to the 1-1 sub-pixel. The 2-6 driving voltage line DVL2f may be electrically connected to the 2-3 sub-pixel disposed adjacent to the other side of the 2-2 sub-pixel in the second direction DR2. The second driving voltage line DVL2 may be repeatedly disposed in the second direction DR2.

The 2-1 driving voltage line DVL2a of another second driving voltage line DVL2 among the plurality of second driving voltage lines DVL2 may be connected to an upper end of the 1-1 driving voltage line DVLla, and the 2-6 driving voltage line DVL2f of another second driving voltage line DVL2 may be electrically connected to the 2-2 sub-pixel. The 2-4 driving voltage line DVL2d of another second driving voltage line DVL2 may be disposed between the 1-2 sub-pixel and the 2-2 sub-pixel.

The third driving voltage line DVL3 may be electrically connected to the 1-2 driving voltage line DVL1b. The plurality of third driving voltage lines DVL3 may be provided. The plurality of third driving voltage lines DVL3 may be repeatedly disposed in the second direction DR2.

Any one of the plurality of third driving voltage lines DVL3 may include a 3-1 driving voltage line DVL3a extending in the second direction DR2 and electrically connected to the 1-2 driving voltage line DVL1b, a 3-2 driving voltage line DVL3b connected to the 3-1 driving voltage line DVL3a and extending in the first direction DR1, a 3-3 driving voltage line DVL3c branched from the 3-2 driving voltage line DVL3b and extending to the other side in the second direction DR2, a 3-4 driving voltage line DVL3d extending by being bent to one side in the second direction DR2 from the 3-2 driving voltage line DVL3b, a 3-5 driving voltage line DVL3e extending by being bent to the other side in the first direction DR1 from the 3-4 driving voltage line DVL3d, and a 3-6 driving voltage line DVL3f extending by being bent to one side in the second direction DR2 from the 3-5 driving voltage line DVL3e. The 3-2 driving voltage line DVL3b may be disposed between the 4-1 sub-pixel and the 4-2 sub-pixel and electrically connected to the 4-1 sub-pixel. The 3-6 driving voltage line DVL3f may be electrically connected to the 3-3 sub-pixel disposed adjacent to one side of the 3-1 sub-pixel in the second direction DR2. The third driving voltage line DVL3 may be repeatedly disposed in the second direction DR2. The 3-4 driving voltage line DVL3d of one third driving voltage line DVL3 may be disposed between the 3-1 sub-pixel and the 4-1 sub-pixel.

The 3-1 driving voltage line DVL3a of another third driving voltage line DVL3 among the plurality of third driving voltage lines DVL3 may be connected to a lower end of the 1-2 driving voltage line DVL1b, and the 3-6 driving voltage line DVL3f of another third driving voltage line DVL3 may be electrically connected to the 3-1 sub-pixel. The 3-4 driving voltage line DVL3d of another third driving voltage line DVL3 may be disposed between the 3-2 sub-pixel and the 4-2 sub-pixel.

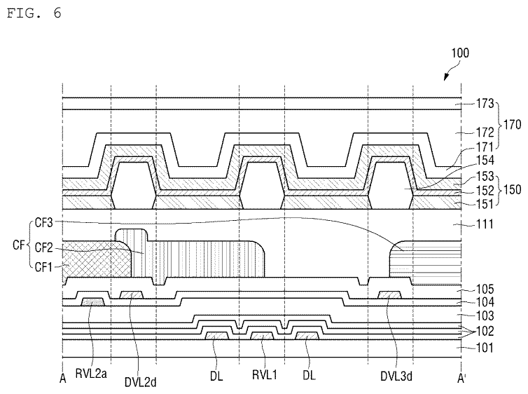

FIG. 6 is a cross-sectional view along line A-A′ in FIG. 5.

Referring to FIGS. 5 and 6, the data line DL and the first reference voltage line RVL1 may be disposed on the first conductive layer. The first reference voltage line RVL1 may be disposed between the second sub-pixel SP2 and the third sub-pixel SP3. The 2-1 reference voltage line RVL2a may be disposed on a semiconductor layer and located coplanarly with the first semiconductor layer 123 of FIG. 4.

The 2-4 driving voltage line DVL2d and the 3-4 driving voltage line DVL3d may be disposed between the first sub-pixel SP1 and the second sub-pixel SP2 and between the third sub-pixel SP3 and the fourth sub-pixel SP4, respectively.

Color filters CF1, CF2, and CF3 may be disposed on the third insulating layer 105. The first color filter CF1 may be disposed in the first sub-pixel SP1, the second color filter CF2 may be disposed in the second sub-pixel SP2, and the third color filter CF3 may be disposed in the fourth sub-pixel SP4.

The first protective layer 111 may be disposed on the color filter CF. The first protective layer 111 may be directly disposed on upper surfaces of the color filters CF1, CF2, and CF3. The first protective layer 111 may be directly disposed on an upper surface of the third insulating layer 105 in the third sub-pixel SP3.

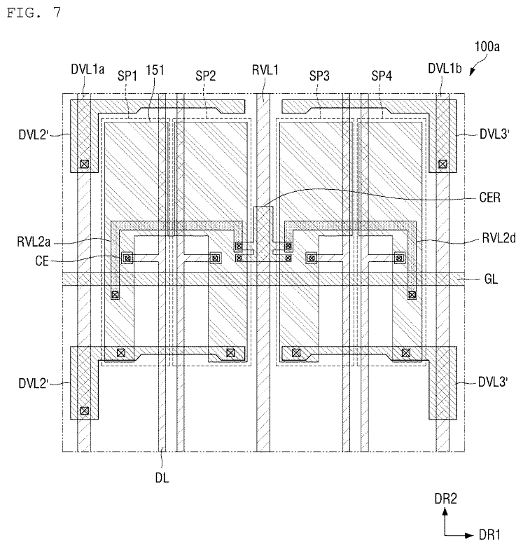

FIG. 7 is a plan view showing a plurality of sub-pixel columns, a driving voltage line, and a reference voltage line according to a comparative example.

Referring to FIGS. 5 to 7, sub-pixel columns of a display panel according to a comparative example may not be disposed alternately. For example, each sub-pixel column may be disposed to fully overlap an adjacent sub-pixel column in the first direction Dr1. In other words, the sub-pixels SP1, SP2, SP3, and SP4 may be arranged in a matrix manner.

The first to fourth sub-pixel columns may each be electrically connected to the reference voltage line RVL. The reference voltage line RVL may be disposed between the second sub-pixel column and the third sub-pixel column. The reference voltage line RVL may include a first reference voltage line RVL1 and a second reference voltage line RVL2 electrically connected to the first reference voltage line RVL1. The first reference voltage line RVL1 may be located on the first conductive layer, but is not limited thereto. The second driving voltage line RVL2 may be electrically connected to the first reference voltage line RVL1 through a connection reference electrode CER. The connection reference electrode CER may be disposed between the second sub-pixel column and the third sub-pixel column. The second reference voltage line RVL2 may electrically connect the connection reference electrode CER with each sub-pixel column. The second reference voltage line RVL2 may be located coplanarly with the first semiconductor layer 123 of FIG. 4. The second reference voltage line RVL2 may be electrically connected to each of the first to fourth sub-pixel columns. To this end, the second reference voltage line RVL2 may include a 2-1 reference voltage line RVL2a electrically connected to the first sub-pixel column, a 2-2 reference voltage line RVL2b electrically connected to the second sub-pixel column, a 2-3 reference voltage line RVL2c electrically connected to the third sub-pixel column, and a 2-4 reference voltage line RVL2d electrically connected to the fourth sub-pixel column.

The driving voltage line DVL may include the first driving voltage lines DVLla and DVL1b, a second driving voltage line DVL2′, and a third driving voltage line DVL3′.

The first driving voltage lines DVLla and DVL1b may include the 1-1 driving voltage line DVLla located at the other side of the first sub-pixel column in the first direction DR1, and the 1-2 driving voltage line DVL1b located at one side of the fourth sub-pixel column in the first direction DR1. The first to fourth sub-pixel columns may be arranged in the first direction DR1 and repeatedly disposed in the first direction DR1. Therefore, the 1-2 driving voltage line DVL1b may be the same line as the 1-1 driving voltage line DVLla. However, for convenience of description, the 1-1 driving voltage line DVLla and the 1-2 driving voltage line DVL1b will be described separately. The second driving voltage line DVL2′ and the third driving voltage line DVL3′ may be electrically connected to the first driving voltage lines DVLla and DVL1b, respectively. Since the 1-1 driving voltage line DVLla and the 1-2 driving voltage line DVL1b may be the same line, the second driving voltage line DVL2′ and the third driving voltage line DVL3′ that are electrically connected to the first driving voltage lines DVLla and DVL1b, respectively may also be substantially the same line. However, for convenience of description, the second driving voltage line DVL2′ and the third driving voltage line DVL3′ will be described separately.

The second driving voltage line DVL2′ may be electrically connected to the 1-1 driving voltage line DVLla. The plurality of second driving voltage lines DVL2′ may be provided. The plurality of second driving voltage lines DVL2′ may be repeatedly disposed in the second direction DR2.

The second driving voltage line DVL2′ may extend in the second direction DR2, may be electrically connected to the 1-1 driving voltage line DVLla, and may extend by being bent to one side in the first direction DR1 so as to be electrically connected to each of the first sub-pixel column and the second sub-pixel column.

The third driving voltage line DVL3′ may extend in the second direction DR2, may be electrically connected to the 1-2 driving voltage line DVL1b, and may extend by being bent to the other side in the first direction DR1 so as to be electrically connected to each of the third sub-pixel column and the fourth sub-pixel column.

In the display device according to the comparative example, since adjacent sub-pixels SP1, SP2, SP3, and SP4 are arranged in a matrix manner, there may be a high possibility of light color mixing between adjacent sub-pixel columns.

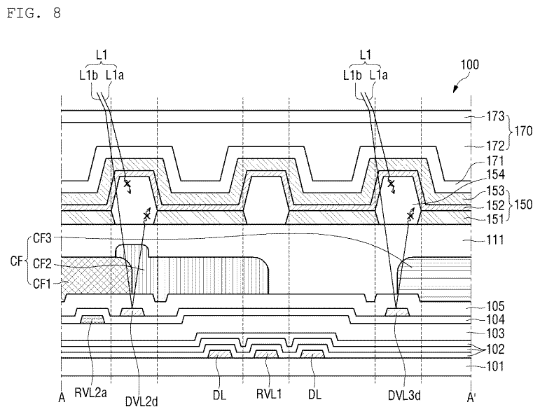

FIG. 8 is a schematic view showing that light color mixing of the display device according to the first embodiment has been prevented.

Referring to FIGS. 1 to 8, the display panel 100 of the display device 10 according to the first embodiment may have blocking electrodes additionally disposed to prevent the light color mixing between adjacent sub-pixel columns. The blocking electrode may be the 2-4 driving voltage line DVL2d of the second driving voltage line DVL2 and the 3-4 driving voltage line DVL3d of the third driving voltage line DVL3 that have been described above in FIG. 6. The 2-4 driving voltage line DVL2d may be disposed between the first sub-pixel SP1 and the second sub-pixel SP2, and the 3-4 driving voltage line DVL3d may be disposed between the third sub-pixel SP3 and the fourth sub-pixel SP4. As shown in FIG. 8, external light L1 may be incident on the display panel 100. Some L1a of the external light L1 may be absorbed by the bank 154 and may no longer be incident on a lower portion of the bank 154. However, the others L1b of the external light L1 may enter the lower portion of the bank 154 without being absorbed by the bank 154. The others L1b may be re-reflected from the lower portion of the bank 154 and provided to adjacent sub-pixels SP2, SP3, and SP4 (in the case of SP1). In this case, light color mixing may occur between the adjacent sub-pixels SP1, SP2, SP3, and SP4.

However, in the case of the display device 10 according to the first embodiment, the second and third driving voltage lines DVL2 and DLV3 may be disposed between the adjacent sub-pixels SP1, SP2, SP3, and SP4 to reflect the others L1b and change an optical path back to the bank 154. The others L1b of which the optical path has been changed may be absorbed by the bank 154.

The display device according to various embodiments of the present specification may be described as follows.

According to various embodiments of the present specification, the display device includes a first sub-pixel column including a plurality of first sub-pixels disposed in a first direction, a second sub-pixel column including a plurality of second sub-pixels disposed in the first direction and disposed at one side of the first sub-pixel column in a second direction intersecting the first direction, and a driving voltage line including a first driving voltage line disposed at the other side of the first sub-pixel in the second direction and extending along the first sub-pixel column and a second driving voltage line electrically connected to the first driving voltage line and electrically connected to a 1-1 sub-pixel among the plurality of first sub-pixels and a 2-1 sub-pixel among the plurality of second sub-pixels, in which the first sub-pixel column and the second sub-pixel column are disposed alternately, and the second driving voltage line is disposed between the first sub-pixel column and the second sub-pixel column.

According to various embodiments of the present specification, the second driving voltage line may include a first portion connected to the first driving voltage line and extending in the second direction from the other side of the 1-1 sub-pixel in the first direction, and a second portion protruding from the first portion toward the 1-1 sub-pixel, and the second portion may be connected to the 1-1 sub-pixel.

According to various embodiments of the present specification, the second driving voltage line may include a first portion connected to the first driving voltage line and extending in the second direction from the other side of the 1-1 sub-pixel in the first direction, and a second portion protruding from the first portion toward the 1-1 sub-pixel, and the second portion may be connected to the 1-1 sub-pixel.

The plurality of first sub-pixels may further include a 1-2 sub-pixel disposed adjacent to the other side of the 1-1 sub-pixel in the first direction, and the first portion may be disposed between the 1-1 sub-pixel and the 1-2 sub-pixel.

According to various embodiments of the present specification, the second driving voltage line may further include a third portion bent from the first portion and extending toward the other side in the first direction, the second sub-pixels may further include a 2-2 sub-pixel disposed adjacent to the other side of the 1-2 sub-pixel in the first direction, and the third portion may be disposed between the 1-2 sub-pixel and the 2-1 sub-pixel.

According to various embodiments of the present specification, the third portion may be connected to the 2-2 sub-pixel.

According to various embodiments of the present specification, the display device may include a plurality of third sub-pixels disposed in the first direction, and further include a third sub-pixel column disposed at one side of the second sub-pixel column in the second direction and a fourth sub-pixel column including a plurality of fourth sub-pixels disposed in the first direction and disposed at one side of the third sub-pixel column in the second direction, in which the third sub-pixel column is disposed alternately with the second sub-pixel column, and the fourth sub-pixel column is disposed alternately with the third sub-pixel column.

According to various embodiments of the present specification, the display device may further include a first reference voltage line disposed between the second sub-pixel column and the third sub-pixel column, extending in the first direction, and electrically connected to the first to fourth sub-pixel columns.

According to various embodiments of the present specification, the display device may further include a second reference voltage line electrically connecting the first reference voltage line with the first to fourth sub-pixel columns.

According to various embodiments of the present specification, the second reference voltage line may be disposed coplanarly with a semiconductor layer of a transistor of the first sub-pixel.

According to various embodiments of the present specification, the first driving voltage line may be located on a first conductive layer, and the second driving voltage line may be located on a second conductive layer disposed on the first conductive layer.

It will be apparent to those skilled in the art that various modifications and variations can be made in the display device of the present disclosure without departing from the technical idea or scope of the disclosure. Thus, it is intended that the present disclosure cover the modifications and variations of this disclosure provided they come within the scope of the appended claims and their equivalents.

### DESCRIPTION OF REFERENCE NUMERALS

10: display device
SPCB1, SPCB2: first source printed circuit board, second source printed circuit board
CPCB: control printed circuit board
FFC: flexible flat cable
SF: source film
RVL: reference voltage line
DVL: driving voltage line

What is claimed is:

1. A display device, comprising:
a first sub-pixel column including a plurality of first sub-pixels disposed in a first direction, and a second sub-pixel column including a plurality of second sub-pixels disposed in the first direction and disposed at one side of the first sub-pixel column in a second direction intersecting the first direction; and
a driving voltage line including a first driving voltage line disposed at the other side of the first sub-pixel in the second direction and extending along the first sub-pixel column, and a second driving voltage line electrically connected to the first driving voltage line and electrically connected to a 1-1 sub-pixel among the plurality of first sub-pixels and a 2-1 sub-pixel among the plurality of second sub-pixels,
wherein the first sub-pixel column and the second sub-pixel column are disposed alternately, and
the second driving voltage line is disposed between the first sub-pixel column and the second sub-pixel column.

2. The display device of claim 1, wherein the second driving voltage line includes a first portion connected to the first driving voltage line and extending in the second direction from the other side of the 1-1 sub-pixel in the first direction, and a second portion protruding from the first portion toward the 1-1 sub-pixel, and the second portion is connected to the 1-1 sub-pixel.

3. The display device of claim 2, wherein the plurality of first sub-pixels further includes a 1-2 sub-pixel disposed adjacent to the other side of the 1-1 sub-pixel in the first direction, and the first portion is disposed between the 1-1 sub-pixel and the 1-2 sub-pixel.

4. The display device of claim 3, wherein the second driving voltage line further includes a third portion bent from the first portion and extending toward the other side in the first direction, the second sub-pixels further includes a 2-2 sub-pixel disposed adjacent to the other side of the 1-2 sub-pixel in the first direction, and the third portion is disposed between the 1-2 sub-pixel and the 2-1 sub-pixel.

5. The display device of claim 4, wherein the third portion is connected to the 2-2 sub-pixel.

6. The display device of claim 1, comprising a plurality of third sub-pixels disposed in the first direction, and further comprising a third sub-pixel column disposed at one side of the second sub-pixel column in the second direction and a fourth sub-pixel column including a plurality of fourth sub-pixels disposed in the first direction and disposed at one side of the third sub-pixel column in the second direction, in which the third sub-pixel column is disposed alternately with the second sub-pixel column, and the fourth sub-pixel column is disposed alternately with the third sub-pixel column.

7. The display device of claim 6, further comprising a first reference voltage line disposed between the second sub-pixel column and the third sub-pixel column, extending in the first direction, and electrically connected to the first to fourth sub-pixel columns.

8. The display device of claim 7, further comprising a second reference voltage line electrically connecting the first reference voltage line with the first to fourth sub-pixel columns.

9. The display device of claim 8, wherein the second reference voltage line is disposed coplanarly with a semiconductor layer of a transistor of the first sub-pixel.

10. The display device of claim 1, wherein the first driving voltage line is located on a first conductive layer, and the second driving voltage line is located on a second conductive layer disposed on the first conductive layer.
